(19) United States
(12) Patent Application Publication
(10) Pub. No.: US 2014/0166063 A1
(43) Pub. Date: Jun. 19, 2014

(54) THERMOELECTRIC DEVICE AND METHOD OF FABRICATING THE SAME

(71) Applicant: Electronics and Telecommunications Research Institute, Daejeon (KR)

(72) Inventor: Moon Gyu JANG, Daejeon (KR)

(73) Assignee: Electronics and Telecommunications Research Institute, Daejeon (KR)

(21) Appl. No.: 14/018,682

(22) Filed: Sep. 5, 2013

(30) Foreign Application Priority Data
Dec. 13, 2012 (KR) 10-2012-0145572

(51) Int. Cl. H01L 35/32; H01L 35/34

(52) U.S. Cl. CPC H01L 35/32; H01L 35/34
USPC 136/205; 438/54

(57) ABSTRACT

Thermoelectric devices are provided. First and second electrodes are provided on a substrate. A first leg including first semiconductor patterns and a first barrier pattern is provided on a first electrode. A second leg including second semiconductor patterns and a second barrier pattern is provided on the second electrode. A third electrode is provided on the first leg and the second leg. The first barrier pattern includes a metal-semiconductor compound including a first metal, and the second barrier pattern includes a metal-semiconductor compound including a second metal. A work function of the second metal is greater than a work function of the first metal.

### CROSS-REFERENCE TO RELATED APPLICATIONS

This U.S. non-provisional patent application claims priority under 35 U.S.C. §119 to Korean Patent Application No. 10-2012-0145572, filed on Dec. 13, 2012, the entirety of which is incorporated by reference herein.

### BACKGROUND

The inventive concept relates to thermoelectric devices and, more particularly, to thermoelectric devices applied with semiconductor processes and methods of fabricating the same.

Thermoelectric devices may convert thermal energy into electrical energy. Recently, the thermoelectric devices attract public attention by clean energy policies. A thermoelectric effect was discovered by Thomas Seebeck in the 1800s. Seebeck connected bismuth to copper and disposed a compass therein. When one side of bismuth was heated, a current was induced by a temperature difference. The compass was operated by a magnetic field caused by the induced current, such that the thermoelectric effect was discovered.

A figure of merit (ZT) value is used as an index for a thermoelectric efficiency. The ZT value is proportional to the square of a seebeck coefficient and electrical conductivity. The ZT value is inversely proportional to thermal conductivity. A metal has a low seebeck coefficient. Additionally, the electrical conductivity of the metal is proportional to the thermal conductivity of the metal by Wiedemann Franz law. Thus, there is a limit to the improvement of the ZT value of the metal. Bi₂Te₃ is mainly used as a material for the thermoelectric devices. However, the thermoelectric devices of Bi₂Te₃ may use a heavy metal. Additionally, it may be difficult to reuse the thermoelectric devices of Bi₂Te₃. Moreover, the thermoelectric devices of Bi₂Te₃ may have a low mechanical strength and a weak moisture characteristic. Furthermore, it may be difficult to reduce sizes of the thermoelectric devices of Bi₂Te₃.

### SUMMARY

Embodiments of the inventive concept are directed to thermoelectric devices and methods of fabricating the same.

In one aspect, a thermoelectric device may include: a first electrode and a second electrode disposed on a substrate; a first leg provided on the first electrode, the first leg including first semiconductor patterns and at least one first barrier pattern; a second leg provided on the second electrode, the second leg including second semiconductor patterns and at least one second barrier pattern; and a third electrode provided on the first leg and the second leg. The first barrier pattern may include a metal-semiconductor compound including a semiconductor material of the first semiconductor patterns and a first metal. The second barrier pattern may include a metal-semiconductor compound including a semiconductor material of the second semiconductor patterns and a second metal. A work function of the second metal may be greater than a work function of the first metal.

In an embodiment, the work function of the first metal may be less than a work function of the first semiconductor patterns; and the work function of the second metal may be greater than a work function of the second semiconductor patterns.

In an embodiment, an electrical conductivity of the first barrier pattern may be greater than an electrical conductivity of the first semiconductor patterns; and an electrical conductivity of the second barrier pattern may be greater than an electrical conductivity of the second semiconductor patterns.

In an embodiment, a thermal conductivity of the first leg may be reduced at an interface between the first semiconductor pattern and the first barrier pattern; and a thermal conductivity of the second leg may be reduced at an interface between the second semiconductor pattern and the second barrier pattern.

In an embodiment, a thermal conductivity of the first barrier pattern may be less than a thermal conductivity of the first semiconductor patterns; and a thermal conductivity of the second barrier pattern may be less than a thermal conductivity of the second semiconductor patterns.

In an embodiment, the first barrier pattern may be provided between the first semiconductor patterns; and the second barrier pattern may be provided between the second semiconductor patterns.

In an embodiment, the first barrier pattern may be further provided between the first electrode and the first semiconductor patterns and between the third electrode and the first semiconductor patterns; and the second barrier pattern may be further provided between the second electrode and the second semiconductor patterns and between the third electrode and the second semiconductor patterns.

In an embodiment, the first semiconductor patterns and the second semiconductor patterns may include silicon (Si) or germanium (Ge).

In an embodiment, the first semiconductor patterns may be N-type semiconductor patterns; and the second semiconductor patterns may be P-type semiconductor patterns.

In an embodiment, the third electrode may be connected in common to the first leg and the second leg.

In an embodiment, the first barrier pattern and the second barrier pattern may include metal elements different from each other, respectively.

In an embodiment, the metal element in the first barrier pattern may include at least one of erbium (Er), samarium (Sm), europium (Eu), nickel (Ni), cobalt (Co), and titanium (Ti).

In an embodiment, the metal element in the second barrier pattern may include at least one of platinum (Pt), nickel (Ni), cobalt (Co), and titanium (Ti).

In an embodiment, an atomic mass of the first metal may be greater than an atomic mass of the first semiconductor patterns; and an atomic mass of the second metal may be greater than an atomic mass of the second semiconductor patterns.

In an embodiment, the first electrode, the second electrode, and the third electrode may include at least one of aluminum (Al), copper (Cu), tungsten (W), titanium (Ti), silver (Ag), gold (Au), platinum (Pt), nickel (Ni), carbon (C), molybdenum (Mo), tantalum (Ta), iridium (Ir), ruthenium (Ru), zinc (Zn), tin (Sn), and indium (In).

In an embodiment, the first leg may include a plurality of first legs; and the second leg may include a plurality of second legs.

In an embodiment, the first barrier pattern may form an ohmic contact with the first semiconductor pattern; and the second barrier pattern may form an ohmic contact with the second semiconductor pattern.

In another aspect, a method of fabricating a thermoelectric device may include: forming a first preliminary leg including a plurality of first semiconductor layers and at least one first metal layer disposed between the first semiconductor layers; forming a second preliminary leg including a plurality of second semiconductor layers and at least one second metal layer disposed between the second semiconductor layers; disposing the first preliminary leg and the second preliminary leg on a first electrode and a second electrode, respectively; and forming a third electrode connected in common to the first preliminary leg and the second preliminary leg. A work function of the second metal layer may be greater than a work function of the first metal layer.

In an embodiment, the method may further include: thermally treating the first preliminary leg and the second preliminary leg.

In an embodiment, the first metal layer may react with the first semiconductor layers to form a first metal-semiconductor compound layer by the thermal treatment; and the second metal layer may react with the second semiconductor layers to form a second metal-semiconductor compound layer by the thermal treatment.

### BRIEF DESCRIPTION OF THE DRAWINGS

The inventive concept will become more apparent in view of the attached drawings and accompanying detailed description.

FIG. 1 is a cross-sectional view illustrating a thermoelectric device according to exemplary embodiments of the inventive concept; and

FIGS. 2A, 2B, 3A, 3B, and 4 are cross-sectional views illustrating a method of fabricating a thermoelectric device according to exemplary embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

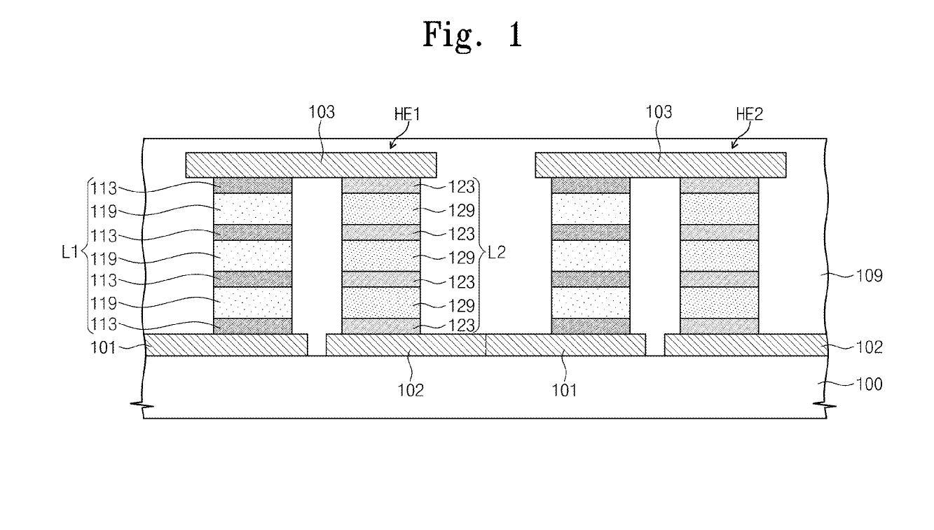

FIG. 1 is a cross-sectional view illustrating a thermoelectric device according to exemplary embodiments of the inventive concept.

Referring to FIG. 1, a plurality of thermoelectric devices HE1 and HE2 may be provided on a base substrate 100. Each of the thermoelectric devices HE1 and HE2 may include a first electrode 101 and a second electrode 102 disposed on the base substrate 100. The second electrode 102 of a first thermoelectric device HE1 may be connected to the first electrode 101 of a second thermoelectric device HE2 adjacent to the first thermoelectric device HE1. In an embodiment, the second electrode 102 of the first thermoelectric device HE1 and the first electrode 101 of the second thermoelectric device HE2 may be formed of one layer without an interface therebetween.

The base substrate 100 may be a semiconductor substrate, an insulated semiconductor substrate, or an insulating substrate. The first electrode 101 and the second electrode 102 may include a metal, a conductive metal nitride, and/or a doped semiconductor material. In an embodiment, the first and second electrodes 101 and 102 may include at least one of aluminum (Al), copper (Cu), tungsten (W), titanium (Ti), silver (Ag), gold (Au), platinum (Pt), nickel (Ni), carbon (C), molybdenum (Mo), tantalum (Ta), iridium (Ir), ruthenium (Ru), zinc (Zn), tin (Sn), and indium (In).

A first leg L1 may be provided on the first electrode 101, and a second leg L2 may be provided on the second electrode 102. A third electrode 103 may be provided on the first and second legs L1 and L2. The third electrode 103 may be connected in common to the first and second legs L1 and L2. The third electrode 103 may function as a heat absorption part (i.e., a high temperature electrode) of the thermoelectric device. The first and second electrodes 101 and 102 may function as a heat exhaust part (i.e., a low temperature electrode) of the thermoelectric device.

The first leg L1 may include a plurality of first semiconductor patterns 119 and at least one first barrier pattern 113 disposed between the first semiconductor patterns 119. The second leg L2 may include a plurality of second semiconductor patterns 129 and at least one second barrier pattern 123 disposed between the second semiconductor patterns 129. The first barrier pattern 113 may also be provided between the first electrode 101 and the first semiconductor patterns 119 and between the third electrode 103 and the first semiconductor patterns 119. The second barrier pattern 123 may also be provided between the second electrode 102 and the second semiconductor patterns 129 and between the third electrode 103 and the second semiconductor patterns 129.

The first leg L1 and the second leg L2 may be physically separated from each other by a protection insulating layer 109. The protection insulating layer 109 may include silicon oxide and/or silicon oxynitride.

The first semiconductor patterns 119 and the second semiconductor patterns 129 may include silicon (Si) or germanium (Ge). The first semiconductor patterns 119 may have a conductivity type different from a conductivity type of the second semiconductor patterns 129. In an embodiment, the conductivity type of the first semiconductor patterns 119 may be an N-type, and the conductivity type of the second semiconductor patterns 129 may be a P-type. A concentration of N-type dopants of the first semiconductor patterns 119 may be about 5×10¹⁹ atm/cm³. A concentration of P-type dopants of the second semiconductor patterns 129 may be about 5×10¹⁹ atm/cm³.

The first barrier pattern 113 and the second barrier pattern 123 may include metal-semiconductor compounds. The first barrier pattern 113 may include a metal-semiconductor compound including a semiconductor material of the first semiconductor pattern 119 and a first metal. The second barrier pattern 123 may include a metal-semiconductor compound including a semiconductor material of the second semiconductor pattern 129 and a second metal. In an embodiment, the first and second barrier patterns 113 and 123 may include silicon layers.

Thermal conductivities of the first leg L1 and the second leg L2 may be reduced by the first barrier pattern 113 and the second barrier pattern 123. In other words, the thermal conductivity of the first leg L1 may be reduced by a phonon scattering phenomenon caused at an interface between the first semiconductor pattern 119 and the first barrier pattern 113, the thermal conductivity of the second leg L2 may be reduced by a phonon scattering phenomenon caused at an interface between the second semiconductor pattern 129 and the second barrier pattern 123.

A thermal conductivity of the first barrier pattern 113 may be less than a thermal conductivity of the first semiconductor patterns 119, and a thermal conductivity of the second barrier pattern 123 may be less than a thermal conductivity of the second semiconductor patterns 129. The thermal conductivities of the first and second semiconductor patterns 119 and 129 (i.e., a doped semiconductor material) are greater than a thermal conductivity of a conventional material (e.g., Bi₂Te₃) for a thermoelectric device. Thus, a ZT value of a thermoelectric device may be low. However, in the thermoelectric device according to embodiments of the inventive concept, the thermal conductivities of the legs L1 and L2 may be reduced by the first and second barrier patterns 113 and 123. Additionally, electrical conductivities of the first and second barrier patterns 113 and 123 are higher than those of the first and second semiconductor patterns 119 and 129. Thus, the ZT value of the thermoelectric device may be improved.

The first barrier pattern 113 and the second barrier pattern 123 may include metals different from each other, respectively. If the conductivity type of the first semiconductor pattern 119 is the N-type and the conductivity type of the second semiconductor pattern 129 is the P-type, a work function of the second metal in the second barrier pattern 123 may be greater than a work function of the first metal in the first barrier pattern 113. In an embodiment, the work function of the first metal in the first barrier pattern 113 may be less than a work function of the first semiconductor pattern 119, and the work function of the second metal in the second barrier pattern 123 may be greater than a work function of the second semiconductor pattern 129. In an embodiment, the first metal may include at least one of erbium (Er), samarium (Sm), europium (Eu), nickel (Ni), cobalt (Co), and titanium (Ti). The second metal may include at least one having a greater work function than the first metal of platinum (Pt), nickel (Ni), cobalt (Co), and titanium (Ti). An atomic mass of the first metal is greater than an atomic mass of the first semiconductor pattern 119, and an atomic mass of the second metal is greater than an atomic mass of the second semiconductor pattern 129. For example, the first and second metals may include materials having greater atomic masses than silicon, respectively.

The third electrode 103 may absorb heat from the outside of the thermoelectric device, and then the heat may be exhausted through the first and second legs L1 and L2 to the outside of the thermoelectric device. If the heat is applied to the third electrode 103, a potential difference may occur between both ends of the first and second legs L1 and L2, such that a current may flow. In other words, if the first semiconductor patterns 119 have the N-type and the second semiconductor patterns 129 have the P-type, an inner current of the thermoelectric device may flow through the first leg L1 in a direction from the first electrode 101 to the third electrode 103 and may flow through the second leg L2 in a direction from the third electrode 103 to the second electrode 102.

In an energy harvesting device such as the thermoelectric device, control of an inner resistance of the device may greatly influence an efficiency of the device. When a semiconductor material is used in the thermoelectric device and a doping concentration of the semiconductor material exceeds a certain level, the thermal conductivity of the thermoelectric device may increase by carriers, so that a thermoelectric efficiency of the thermoelectric device may be reduced. Thus, the doping concentration of the semiconductor material in the thermoelectric device should maintain a predetermined level within a range of, for example, about 1×10¹⁹ atm/cm³ to about 1×10²⁰ atm/cm³. In this case, a Schottky barrier may be formed at interfaces between the semiconductor layers and barrier layers by a low doping concentration of the semiconductor layers, such that the semiconductor layers and the barrier layers may not constitute complete ohmic contacts.

According to embodiments of the inventive concept, the barrier pattern between the N-type semiconductor patterns may include the material having the relatively low work function, and the barrier pattern between the P-type semiconductor patterns may include the material having the relatively high work function. As a result, interface resistances between the barrier patterns and the semiconductor patterns may be reduced to increase the efficiency of the thermoelectric device.

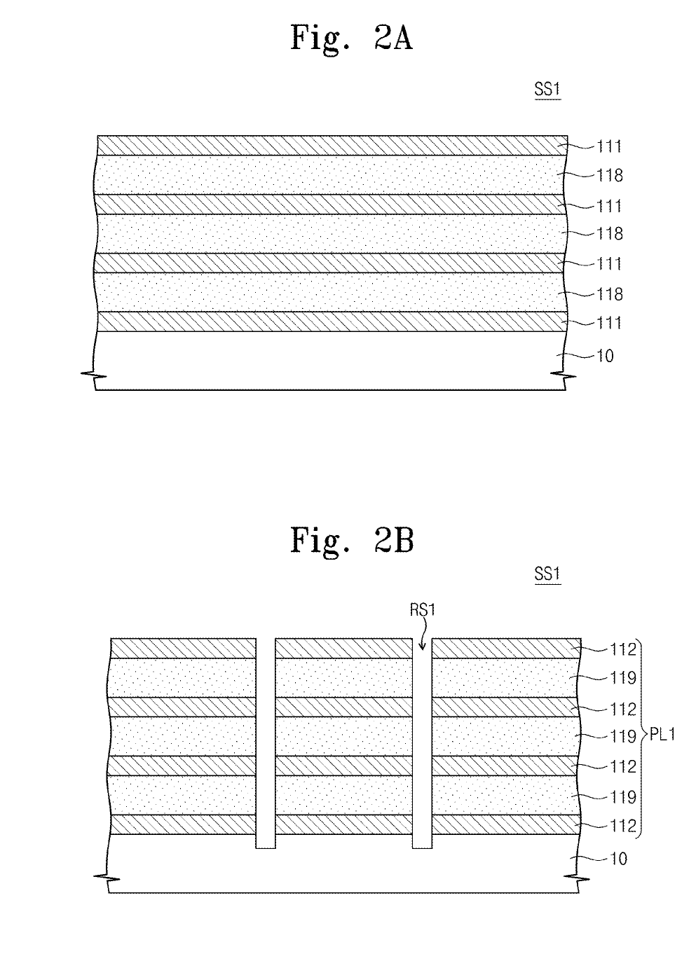

FIGS. 2A, 2B, 3A, 3B, and 4 are cross-sectional views illustrating a method of fabricating a thermoelectric device according to exemplary embodiments of the inventive concept.

Referring to FIG. 2A, first metal layers 111 and first semiconductor layers 118 may be alternately and repeatedly stacked on a first substrate 10, thereby forming a first stack structure SS1. The first substrate 10 may be a semiconductor substrate or an insulating substrate. The first semiconductor layers 118 may be doped with N-type dopants by an in-situ method. The first metal layers 111 may include at least one of erbium (Er), samarium (Sm), europium (Eu), nickel (Ni), cobalt (Co), and titanium (Ti). In an embodiment, the first metal layers 111 and the first semiconductor layers 118 may be formed by a chemical vapor deposition (CVD) process and/or a sputtering process. The first metal layers 111 may be thinner than the first semiconductor layers 118.

Referring to FIG. 2B, the first stack structure SS1 may be divided into first preliminary legs PL1. The dividing process is performed, such that the first preliminary legs PL1 may be separated from each other by recess regions RS1. The first preliminary legs PL1 may include first semiconductor patterns 119 and first metal patterns 112. In an embodiment, the dividing process may include a sawing process.

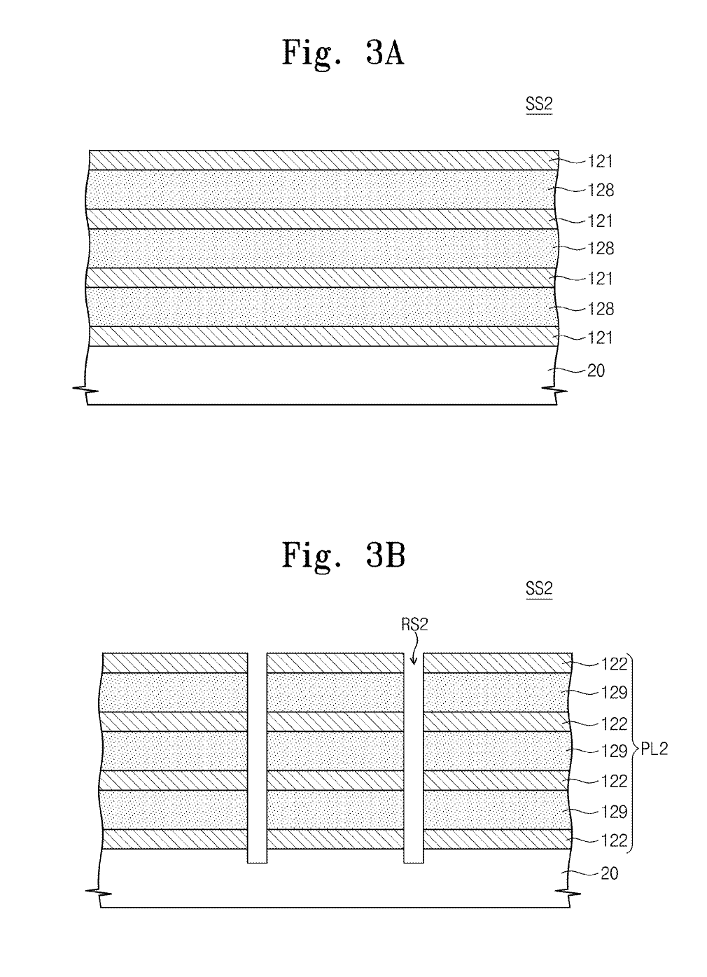

Referring to FIG. 3A, second metal layers 121 and second semiconductor layers 128 may be alternately and repeatedly stacked on a second substrate 20, thereby forming a second stack structure SS2. The second substrate 20 may be a semiconductor substrate or an insulating substrate. The second semiconductor layers 128 may be doped with P-type dopants by an in-situ method. The second metal layers 121 may include at least one having a greater work function than the first metal layer 111 of platinum (Pt), nickel (Ni), cobalt (Co), and titanium (Ti). In an embodiment, the second metal layers 121 and the second semiconductor layers 128 may be formed by a CVD process and/or a sputtering process. The second metal layers 121 may be thinner than the second semiconductor layers 128.

Referring to FIG. 3A, the second stack structure SS2 may be divided into second preliminary legs PL2. The dividing process is performed, such that the second preliminary legs PL2 may be separated from each other by recess regions RS2. The second preliminary legs PL2 may include second semiconductor patterns 129 and second metal patterns 122. In an embodiment, the dividing process of the second stack structure SS2 may include a sawing process.

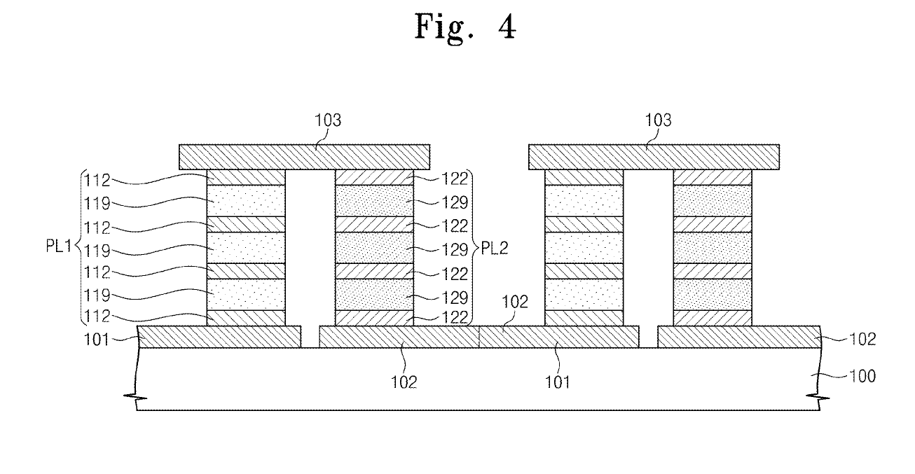

Referring to FIG. 4, a first electrode 101 and a second electrode 102 may be formed on a base substrate 100. The first electrode 101 and the second electrode 102 may include at least one of aluminum (Al), copper (Cu), tungsten (W), titanium (Ti), silver (Ag), gold (Au), platinum (Pt), nickel (Ni), carbon (C), molybdenum (Mo), tantalum (Ta), iridium (Ir), ruthenium (Ru), zinc (Zn), tin (Sn), and indium (In). The first electrode 101 and a second electrode 102 may be formed using, for example, a sputtering process.

The first preliminary leg PL1 illustrated in FIG. 2B and the second preliminary leg PL2 illustrated in FIG. 3B may be provided on the first electrode 101 and the second electrode 102, respectively. In an embodiment, a single first preliminary leg PL1 and a single second preliminary leg PL2 may be provided on a single first electrode 101 and a single second electrode 102, respectively. However, the inventive concept is not limited thereto. In another embodiment, a plurality of first preliminary legs PL1 may be provided on the single first electrode 101, and a plurality of second preliminary legs PL2 may be provided on the single second electrode 102. The first and second preliminary legs PL1 and PL2 may be bonded to the first and second electrodes 101 and 102 through thermal-conductive adhesion layers. Alternatively, the first and second preliminary legs PL1 and PL2 may be disposed on the first and second electrodes 101 and 102 without the thermal-conductive adhesion layers. The thermal-conductive adhesion layer may include a metal of which a melting point is lower than a thermal treatment temperature described below. For example, the thermal-conductive adhesion layer may include at least one of silver (Ag), gold (Au), and platinum (Pt).

A third electrode 103 may be formed on the first and second preliminary legs PL1 and PL2. The third electrode 103 may be bonded to the first and second preliminary legs PL1 and PL2 through a thermal-conductive adhesion layer. In another embodiment, after an interlayer insulating layer may be formed to fill a space between the first and second preliminary legs PL1 and PL2, a conductive layer may be deposited on the interlayer insulating layer and then the deposited conductive layer may be patterned to form the third electrode 103. The third electrode 103 may include at least one of aluminum (Al), copper (Cu), tungsten (W), titanium (Ti), silver (Ag), gold (Au), platinum (Pt), nickel (Ni), carbon (C), molybdenum (Mo), tantalum (Ta), iridium (Ir), ruthenium (Ru), zinc (Zn), tin (Sn), and indium (In).

Referring again to FIG. 1, a thermal treatment process may be performed on the first and second preliminary legs PL1 and PL2 to form first and second legs L1 and L2. In an embodiment, the thermal treatment process may be performed at a thermal treatment temperature of about 500 degrees Celsius to about 1200 degrees Celsius. Due to the thermal treatment process, the first metal patterns 112 may react with the first semiconductor patterns 119 adjacent to the first metal patterns 112 to form first barrier patterns 113, and the second metal patterns 122 may react with the second semiconductor patterns 129 adjacent to the second metal patterns 122 to form second barrier patterns 123. Subsequently, a protection insulating layer 109 may be formed to cover the third electrode 103. For example, the protection insulating layer 109 may include a silicon oxide layer and/or a silicon oxynitride layer.

According to embodiments of the inventive concept, the thermoelectric devices capable of reducing the interface resistance between the semiconductor pattern and the barrier pattern may be easily formed.

According to embodiments of the inventive concept, the thermoelectric devices may be fabricated using the semiconductor processes. Since the barrier patterns are provided in the legs, the thermal conductivity of the leg may be reduced and the electrical conductivity of the leg may increase. Additionally, the metals in the barrier patterns may have the work functions different from each other, respectively. Thus, the interface resistances between the semiconductor patterns and the barrier patterns may be reduced.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A thermoelectric device comprising:
a first electrode and a second electrode disposed on a substrate;
a first leg provided on the first electrode, the first leg including first semiconductor patterns and at least one first barrier pattern;
a second leg provided on the second electrode, the second leg including second semiconductor patterns and at least one second barrier pattern; and
a third electrode provided on the first leg and the second leg,
wherein the first barrier pattern includes a metal-semiconductor compound including a semiconductor material of the first semiconductor patterns and a first metal;
wherein the second barrier pattern includes a metal-semiconductor compound including a semiconductor material of the second semiconductor patterns and a second metal; and
wherein a work function of the second metal is greater than a work function of the first metal.

2. The thermoelectric device of claim 1, wherein the work function of the first metal is less than a work function of the first semiconductor patterns; and
wherein the work function of the second metal is greater than a work function of the second semiconductor patterns.

3. The thermoelectric device of claim 1, wherein an electrical conductivity of the first barrier pattern is greater than an electrical conductivity of the first semiconductor patterns; and
wherein an electrical conductivity of the second barrier pattern is greater than an electrical conductivity of the second semiconductor patterns.

4. The thermoelectric device of claim 1, wherein a thermal conductivity of the first leg is reduced at an interface between the first semiconductor pattern and the first barrier pattern; and
wherein a thermal conductivity of the second leg is reduced at an interface between the second semiconductor pattern and the second barrier pattern.

5. The thermoelectric device of claim 1, wherein a thermal conductivity of the first barrier pattern is less than a thermal conductivity of the first semiconductor patterns; and
wherein a thermal conductivity of the second barrier pattern is less than a thermal conductivity of the second semiconductor patterns.

6. The thermoelectric device of claim 1, wherein the first barrier pattern is provided between the first semiconductor patterns; and
wherein the second barrier pattern is provided between the second semiconductor patterns.

7. The thermoelectric device of claim 6, wherein the first barrier pattern is further provided between the first electrode and the first semiconductor patterns and between the third electrode and the first semiconductor patterns; and
wherein the second barrier pattern is further provided between the second electrode and the second semiconductor patterns and between the third electrode and the second semiconductor patterns.

8. The thermoelectric device of claim 1, wherein the first semiconductor patterns and the second semiconductor patterns include silicon (Si) or germanium (Ge).

9. The thermoelectric device of claim 1, wherein the first semiconductor patterns are N-type semiconductor patterns; and
wherein the second semiconductor patterns are P-type semiconductor patterns.

10. The thermoelectric device of claim 1, wherein the third electrode is connected in common to the first leg and the second leg.

11. The thermoelectric device of claim 1, wherein the first barrier pattern and the second barrier pattern include metal elements different from each other, respectively.

12. The thermoelectric device of claim 11, wherein the metal element in the first barrier pattern includes at least one of erbium (Er), samarium (Sm), europium (Eu), nickel (Ni), cobalt (Co), and titanium (Ti).

13. The thermoelectric device of claim 12, wherein the metal element in the second barrier pattern includes at least one of platinum (Pt), nickel (Ni), cobalt (Co), and titanium (Ti).

14. The thermoelectric device of claim 11, wherein an atomic mass of the first metal is greater than an atomic mass of the first semiconductor patterns; and
wherein an atomic mass of the second metal is greater than an atomic mass of the second semiconductor patterns.

15. The thermoelectric device of claim 1, wherein the first electrode, the second electrode, and the third electrode include at least one of aluminum (Al), copper (Cu), tungsten (W), titanium (Ti), silver (Ag), gold (Au), platinum (Pt), nickel (Ni), carbon (C), molybdenum (Mo), tantalum (Ta), iridium (Ir), ruthenium (Ru), zinc (Zn), tin (Sn), and indium (In).

16. The thermoelectric device of claim 1, wherein the first leg includes a plurality of first legs; and
wherein the second leg includes a plurality of second legs.

17. The thermoelectric device of claim 1, wherein the first barrier pattern forms an ohmic contact with the first semiconductor pattern; and
wherein the second barrier pattern forms an ohmic contact with the second semiconductor pattern.

18. A method of fabricating a thermoelectric device, the method comprising:
forming a first preliminary leg including a plurality of first semiconductor layers and at least one first metal layer disposed between the first semiconductor layers;
forming a second preliminary leg including a plurality of second semiconductor layers and at least one second metal layer disposed between the second semiconductor layers;
disposing the first preliminary leg and the second preliminary leg on a first electrode and a second electrode, respectively; and
forming a third electrode connected in common to the first preliminary leg and the second preliminary leg,
wherein a work function of the second metal layer is greater than a work function of the first metal layer.

19. The method of claim 18, further comprising:
thermally treating the first preliminary leg and the second preliminary leg.

20. The method of claim 19, wherein the first metal layer reacts with the first semiconductor layers to form a first metal-semiconductor compound layer by the thermal treatment; and
wherein the second metal layer reacts with the second semiconductor layers to form a second metal-semiconductor compound layer by the thermal treatment.
